(19) United States
(12) Patent Application Publication
(10) Pub. No.: US 2018/0274085 A1
(43) Pub. Date: Sep. 27, 2018

(54) WORKPIECE HOLDING BODY AND FILM-FORMING APPARATUS

(71) Applicant: ULVAC, INC., Chigasaki-shi, Kanagawa (JP)

(72) Inventors: YUU NAKAMUTA, Chigasaki-shi, Kanagawa (JP); MASAHIRO MATSUMOTO, Chigasaki-shi, Kanagawa (JP); MANABU HARADA, Chigasaki-shi, Kanagawa (JP); KOJI TAKAHASHI, Chigasaki-shi, Kanagawa (JP); TAKASHI KAGEYAMA, Chigasaki-shi, Kanagawa (JP)

(21) Appl. No.: 15/756,891

(22) PCT Filed: Aug. 17, 2016
(86) PCT No.: PCT/JP2016/073974

§ 371 Date: Mar. 1, 2018

(30) Foreign Application Priority Data
Sep. 2, 2015 (JP) 2015-172612

(51) Int. Cl. C23C 14/50; C23C 14/34; H01L 21/687; H01L 21/56

(52) U.S. Cl. CPC C23C 14/50; H01L 21/561; H01L 21/68778; C23C 14/3464

(57) ABSTRACT

According to an embodiment of the present invention, the workpiece holding body 20 for surface processing includes the holder 21 and the adhesive sheet 22. The adhesive sheet 22 includes the first surface 22a (the first adhesive layer 221) and the second surface 22b (the second adhesive layer 222), the first surface 22a (the first adhesive layer 221) being bonded to the holder 21 at a first adhesive force, the second surface 22b (the second adhesive layer 222) being capable of holding a workpiece (the component main-body 110) at a second adhesive force, the second adhesive force being higher than the first adhesive force.

### TECHNICAL FIELD

The present invention relates to a workpiece holding body and a film-forming apparatus, which are used to manufacture an electronic component having a protective film, for example.

### BACKGROUND ART

In recent years, electronic devices are downsized and sophisticated. Accordingly, it is also desirable to provide various kinds of further downsized and sophisticated built-in electronic components. To meet such a request, for example, higher-density packages of electronic components are being developed.

There is widely known a technique in which a workpiece/a plurality of workpieces to be processed is/are mounted on a carrier, and the workpiece/workpieces is/are processed while delivering the carrier for a plurality of steps in sequence. In this case, preferably, the workpiece/workpieces can be held on the carrier and can be detachably attached to the carrier easily at the same time. For example, the following Patent Literature 1 discloses a carrier jig. The carrier jig includes a carrier plate, and an adhesive layer provided on the carrier plate. The carrier jig is configured to detachably and adhesively hold a workpiece on the adhesive layer.

### CITATION LIST

### Patent Literature

Patent Literature 1: Japanese Patent Application Laid-open No. 2007-329182

### DISCLOSURE OF INVENTION

### Technical Problem

In order to mount electronic components at a higher density, it is necessary to reduce the space in which each electronic component is mounted. To reduce the space, according to a surface-mount component of the recent trend, a plurality of bump electrodes (bumps) are arrayed in a grid pattern on the bottom surface (mount surface) of a component. Examples of such a surface-mount component include a BGA (Ball Grid Array)/CSP (Chip Size Package), etc.

When a protective film is formed on a surface of a workpiece by using the above-mentioned carrier including an adhesive layer, a film-material also adheres to the surface of the adhesive layer. Because of this, it is necessary to replace the adhesive layer in order to use the carrier again. In view of the above, where the adhesive force of the adhesive layer is decreased in order to replace the adhesive layer easily, the force to hold a workpiece is decreased, which is a problem. Meanwhile, where the adhesive force of the adhesive layer is increased in order to satisfactorily hold a workpiece, it is difficult to replace the adhesive layer, which is a problem.

In view of the above-mentioned circumstances, it is an object of the present invention to provide a workpiece holding body for surface processing and a film-forming apparatus, in which a satisfactory force to hold a workpiece is always attained and, in addition, an adhesive layer can be replaced easily.

### Solution to Problem

To attain the above-mentioned object, according to an embodiment of the present invention, workpiece holding body for surface processing includes a holder and an adhesive sheet.

The adhesive sheet includes a first surface and a second surface, the first surface being bonded to the holder with a first adhesive force, the second surface being capable of holding a workpiece with a second adhesive force, the second adhesive force being higher than the first adhesive force.

Since the adhesive sheet of the workpiece holding body includes a first surface and a second surface, the first surface being bonded to the holder with a first adhesive force, the second surface being capable of holding a workpiece with a second adhesive force, the second adhesive force being higher than the first adhesive force, a satisfactory force to hold a workpiece is always attained and, in addition, an adhesive layer can be replaced easily.

The adhesive sheet may include a base material, a first adhesive layer including the first surface, the first adhesive layer being layered on one surface of the base material, and a second adhesive layer including the second surface, the second adhesive layer being layered on another surface of the base material.

Therefore it is possible to easily configure an adhesive sheet, the adhesive force of the first surface being different from the adhesive force of the second surface.

The second surface may be capable of deforming depending on a form of an attached-surface of the workpiece.

As a result, it is possible for the attached-surface of the workpiece to come in close contact with the second surface. Therefore it is possible to increase the force to hold the workpiece. Further, for example, in the film-forming processing, it is possible to prevent a film-material from coming in contact with the attached-surface.

The holder may include a holder main-body, and a heat-conductive sheet arranged between the holder main-body and the adhesive sheet.

As a result, the heat-diffusion efficiency is increased. Therefore the holder is applicable to plasma surface processing or surface processing that requires a heat source.

The holder has a plate shape and is capable of holding a plurality of workpieces on one surface.

As a result, it is possible to process a plurality of workpieces at one time. Therefore productivity may be increased.

According to an embodiment of the present invention, a film-forming apparatus includes a film-forming chamber, a film-forming source, a support body, and a workpiece holding body.

The film-forming source is provided in the film-forming chamber.

The support body is provided in the film-forming chamber and having a support surface, the support surface being capable of supporting a workpiece.

The workpiece holding body includes a holder detachably attached to the support surface, and an adhesive sheet including a first surface and a second surface, the first surface being bonded to the holder with a first adhesive force, the second surface being configured to be capable of holding a workpiece with a second adhesive force, the second adhesive force being higher than the first adhesive force.

Since the adhesive sheet of the film-forming apparatus includes a first surface and a second surface, the first surface being bonded to the holder with a first adhesive force, the second surface being capable of holding a workpiece with a second adhesive force, the second adhesive force being higher than the first adhesive force, a satisfactory force to hold a workpiece is always attained and, in addition, an adhesive layer can be replaced easily. As a result, a film can be formed on a workpiece appropriately and productivity may be increased at the same time.

The support body may include a cooling mechanism capable of cooling down the support surface, and the holder may include a holder main-body, and a heat-conductive sheet arranged between the holder main-body and the adhesive sheet.

As a result, it is possible to cool down the workpiece at a predetermined temperature. Therefore it is applicable to plasma surface processing or surface processing that requires a heat source.

The support body may include a rotary drum, the rotary drum being capable of rotating in the film-forming chamber and having the support surface formed on a peripheral surface.

As a result, it is possible to form films on a plurality of workpieces at one time. Therefore productivity may be increased.

### Advantageous Effects of Invention

As described above, according to the present invention, a satisfactory force to hold a workpiece is always attained and, in addition, an adhesive layer can be replaced easily.

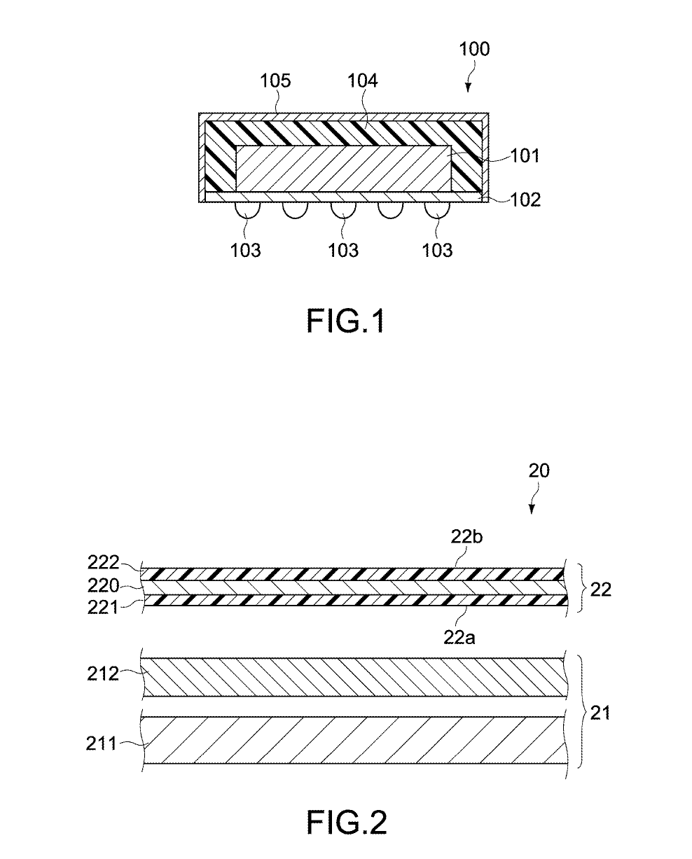

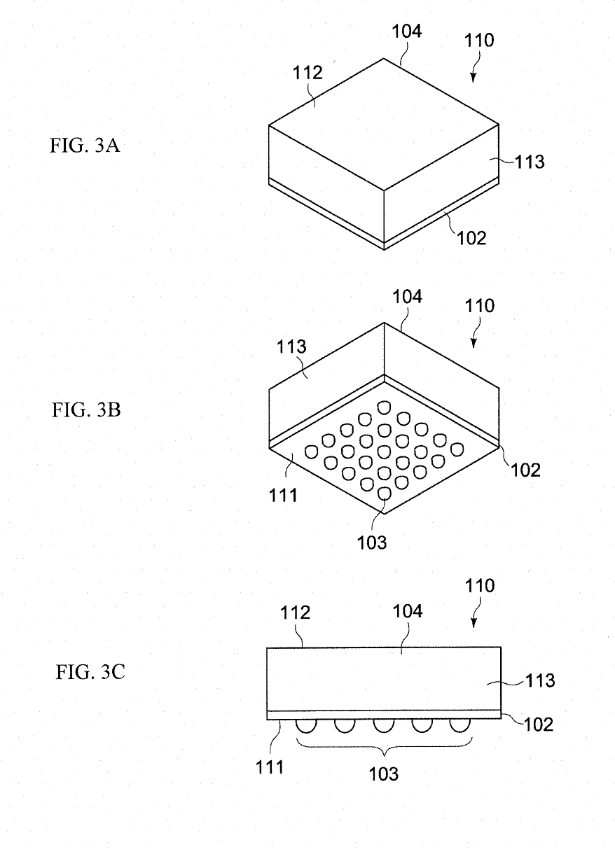

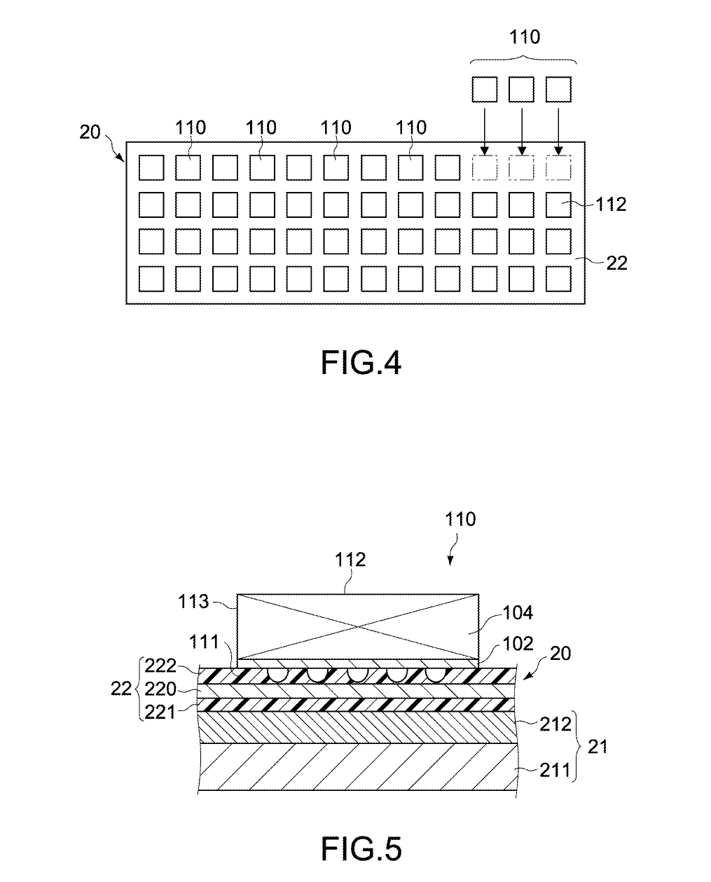

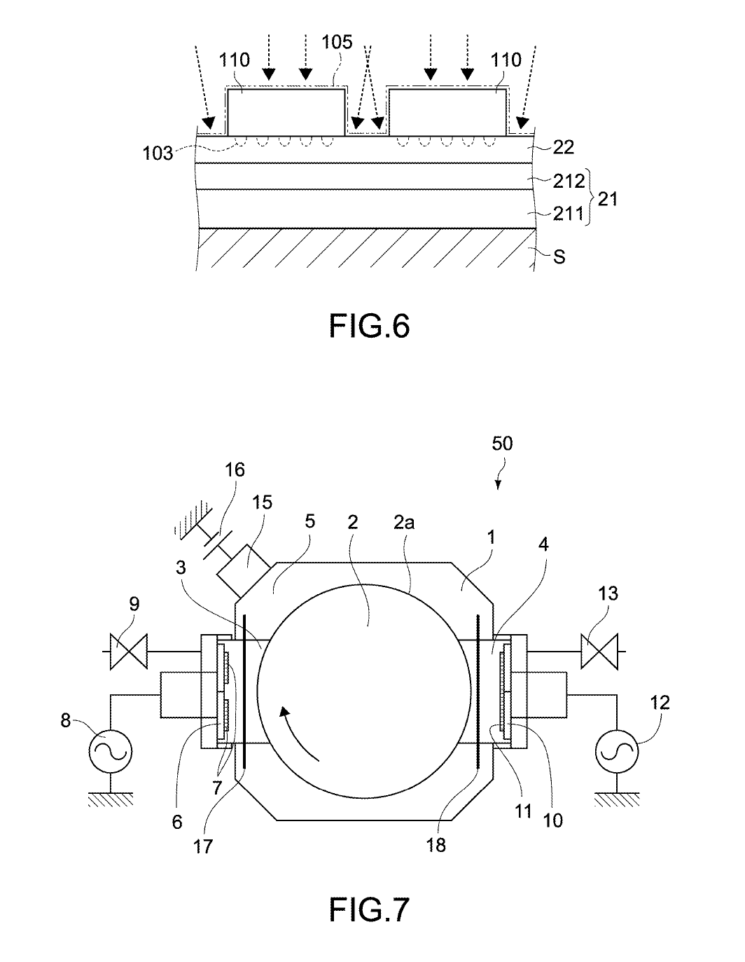

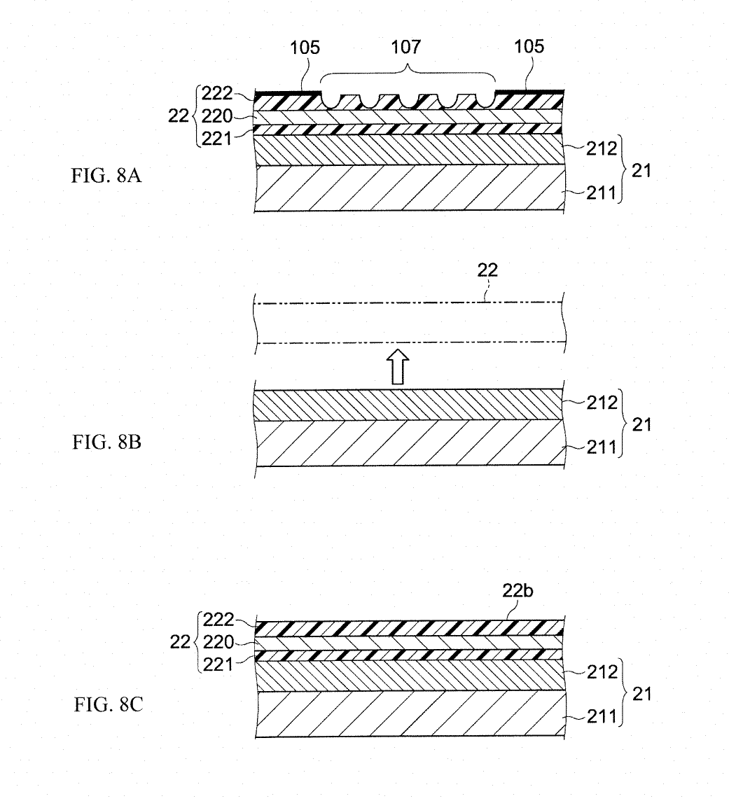

### BRIEF DESCRIPTION OF DRAWINGS

[FIG. 1] A side-cross-sectional view schematically showing the configuration of the electronic component as a workpiece.

[FIG. 2] An exploded side-cross-sectional view showing the workpiece holding body of the present embodiment.

[FIG. 3] Perspective views and a side view each schematically showing the electronic component (component main-body).

[FIG. 4] A plan view schematically showing the workpiece holding body.

[FIG. 5] A side-cross-sectional view schematically and mainly showing how to mount the component main-body on the workpiece holding body.

[FIG. 6] A side-cross-sectional view schematically and mainly showing how to form the protective film on the component main-bodies.

[FIG. 7] A configuration diagram schematically showing a film-forming apparatus used in the film-forming processing.

[FIG. 8] Side-cross-sectional views each schematically and mainly showing the workpiece holding body for illustrating the step of replacing the adhesive sheet.

### MODE(S) FOR CARRYING OUT THE INVENTION

Hereinafter, an embodiment of the present invention will be described with reference to the drawings. In the present embodiment, a workpiece holding body and a film-forming apparatus, each of which is used to manufacture an electronic component of FIG. 1, will be described as an example.

[Electronic Component]

FIG. 1 is a side-cross-sectional view schematically showing the configuration of an electronic component 100 to be manufactured.

As shown in FIG. 1, the electronic component 100 is a BGA/CSP-type semiconductor package component. The electronic component 100 includes a semiconductor chip 101, a wiring board 102 electrically connected to the semiconductor chip 101, a plurality of bumps (bump electrodes) 103 arrayed in a grid pattern on the back surface of the wiring board 102, a resin body 104 for sealing the semiconductor chip 101, and a protective film 105 that coats the top surface and the side peripheral surfaces of the resin body 104.

Note that FIG. 1 schematically shows the bumps 103 to facilitate understanding. The number, the size, the shape, and the like of the bumps 103 may be different from actual bumps (the same applies to hereinafter).

[Workpiece Holding Body]

FIG. 2 is an exploded side-cross-sectional view showing a workpiece holding body 20 of the present embodiment.

As shown in FIG. 2, the workpiece holding body 20 includes a holder 21 and an adhesive sheet 22. The workpiece holding body 20 is used in the step of forming the protective film 105, which is one of the steps of manufacturing the electronic component 100. As described later, the adhesive sheet 22 of the workpiece holding body 20 adhesively holds a workpiece on which a film is to be formed (electronic component on which the protective film 105 is yet to be formed), and such a workpiece holding body 20 is mounted on a film-forming apparatus.

The holder 21 has a layered structure including a holder main-body 211 and a heat-conductive sheet 212. The holder 21 has a plate shape and is capable of holding a plurality of workpieces on one surface.

The holder main-body 211 is a rectangular metal plate such as an aluminum plate, a copper plate, and a stainless steel plate, for example. The shape and the size of the heat-conductive sheet 212 are the same as the shape and the size of the holder main-body 211. The heat-conductive sheet 212 is attached to the top surface of the holder main-body 211. The heat-conductive sheet 212 is a silicone-series resin sheet or an acrylic resin sheet containing heat-conductive fillers. As the heat-conductive sheet 212, typically, an electrically-insulative sheet is used. Alternatively, an electrically-conductive sheet may be used.

The shape and the size of the adhesive sheet 22 are the same as the shape and the size of the holder 21. The adhesive sheet 22 is peelably attached to the surface (surface of the heat-conductive sheet 212) of the holder 21. The adhesive sheet 22 includes a first surface 22a bonded to the surface of the holder 21 with a first adhesive force, and a second surface 22b capable of holding a workpiece with a second adhesive force, the second adhesive force being higher than the first adhesive force.

Typically, the adhesive sheet 22 is a double-sided adhesive tape. The adhesive sheet 22 includes a base material 220, a first adhesive layer 221 that coats one surface (bottom surface of FIG. 2) of the base material 220, and a second adhesive layer 222 that coats the other surface (top surface of FIG. 2) of the base material 220.

The base material 220 is, typically, a resin film such as a PET (polyethylene terephthalate) film and a PI (polyimide) film. Alternatively, the base material 220 may be made of another material such as paper, a non-woven fabric, and glass fibers.

Each of the first adhesive layer 221 and the second adhesive layer 222 is made of an adhesive material having tackiness. The first adhesive layer 221 includes the first surface 22a of the adhesive sheet 22, and is bonded to the holder 20 at the first adhesive force. Meanwhile, the second adhesive layer 222 includes the second surface 22b of the adhesive sheet 22, and is configured to hold a workpiece with the second adhesive force.

The strength of the adhesive force (first adhesive force) of the first adhesive layer 221 is set as follows. The first adhesive layer 221 always has a satisfactory bonding force, with which the adhesive sheet 22 is not removed from the holder 20 when the holder 21 is upside-down as a matter of course and when the holder 21 is accelerated and the like at the time of handling and at the time of film-formation. At the same time, the first adhesive layer 221 can be peeled off from the holder 20 relatively easily. More specifically, the strength of the first adhesive force is between the range of, for example, 0.2N/25 mm to 3.5N/25 mm, where a tape-like sample having a width of 25 mm is used and where the first adhesive force is converted into a peeling strength value.

Meanwhile, the adhesive force (second adhesive force) of the second adhesive layer 222 can be set appropriately depending on the size, the shape, and the like of an attached-surface of a workpiece. The second adhesive force is between the range of, for example, 6.5N/25 mm to 12N/25 mm, where a tape-like sample having a width of 25 mm is used similarly and where the second adhesive force is converted into a peeling strength value. Where the second adhesive force is too low, it is difficult to hold a workpiece appropriately. To the contrary, where the second adhesive force is too high, it is difficult to peel off a workpiece from the adhesive sheet 22.

Each of the first adhesive layer 221 and the second adhesive layer 222 is made of, for example, a silicone-series adhesive resin material, an acrylic bond resin material, or the like. Especially, silicone-series adhesive resin is advantageous because the adhesive force is adjustable within a relatively wide range (for example, 0.2N/25 mm to 9N/25 mm) and because it has relatively high heat resistance and it can be therefore satisfactorily treated at a high temperature.

The thickness of each of the first adhesive layer 221 and the second adhesive layer 222 is not particularly limited, and can be arbitrarily set within a range in which the above-mentioned target bonding force or holding force is obtained.

Especially, since the second adhesive layer 222 includes the second surface 22b, i.e., the surface on which a workpiece is held, the second adhesive layer 222 is preferably configured to be capable of deforming depending on the form of an attached-surface of a workpiece. In order to obtain such properties, for example, the second adhesive layer 222 may be relatively thick, or the base material 220 may be made of a highly deformable material. Alternatively, the second surface 22b may have deformability with the use of elasticity of the heat-conductive sheet 212.

[Method of Manufacturing Electronic Component]

Next, a method of manufacturing the electronic component 100 (method of forming the protective film 105) by using the workpiece holding body 20 configured as described above will be described.

FIG. 3 (A to C) includes a top perspective view, a bottom perspective view, and a side view, each of which shows an electronic component on which the protective film 105 is yet to be formed (hereinafter, referred to as component main-body 110).

As shown in FIG. 3 (A to C), the component main-body 110 schematically has a rectangular parallelepiped shape. The component main-body 110 includes a bottom surface 111 having the plurality of bumps 103, a top surface 112 opposite to the bottom surface 111, and side peripheral surfaces 113 connecting the bottom surface 111 and the top surface 112. The bottom surface 111 corresponds to the back surface of the wiring board 102. The top surface 112 corresponds to the top surface of the resin body 104. The side peripheral surfaces 113 correspond to the four side surfaces of the resin body 104 and the four side surfaces of the wiring board 102.

Typically, such a component main-body 110 is prepared before the step of forming the protective film 105. The component main-body 110 may be manufactured outside or may be a commercial product. The size of the component main-body 110 is also not particularly limited. For example, the component main-body 110 has a plane shape of 3 mm x 3 mm to 25 mm x 25 mm square.

In the present embodiment, a plurality of component main-bodies 110, each of which has the above-mentioned configuration, are mounted on a film-forming apparatus simultaneously. The protective films 105 are formed on the plurality of component main-bodies 110 at one time, respectively. The workpiece holding body 20 is used to handle the plurality of component main-bodies 110.

FIG. 4 is a plan view schematically showing the step of mounting the component main-bodies 110 onto the workpiece holding body 20. FIG. 5 is a side-cross-sectional view schematically and mainly showing how to mount the component main-body 110 on the workpiece holding body 20.

As shown in FIG. 4, the plurality of component main-bodies 110 are mounted on the workpiece holding body 20 in the Y direction and the X direction at predetermined intervals. The number of the component main-bodies 110 is not particularly limited, and is appropriately determined depending on the size of the component main-body 110 and the size of the workpiece holding body 20. For example, several tens to several hundreds of component main-bodies 110 are mounted.

As shown in FIG. 5, the surface (the second surface 22b ) of the adhesive sheet 22 of the workpiece holding body 20 adhesively holds the bottom surface 111 of each component main-body 110. At this time, the plurality of bumps 103 protruding from the bottom surface 111 press the second adhesive layer 222 of the adhesive sheet 22, and thus the second adhesive layer 222 locally deforms. At the same time, the second adhesive layer 222 of the adhesive sheet 22 is squeezed between the bumps 103 and comes in close contact with the bottom surface 111. In this manner, the surface (the second surface 22b ) of the second adhesive layer 222 deforms depending on the form of the attached-surface (the bottom surface 111) of the component main-body 110. As a result, the second adhesive layer 222 coats the entire bottom surface 111 and adhesively holds the component main-body 110 at the same time.

Next, the workpiece holding body 20 is mounted on a film-forming apparatus. Then the protective film 105 is formed on the surfaces (the top surface 112 and the side peripheral surfaces 113) of each component main-body 110. FIG. 6 is a side-cross-sectional view schematically and mainly showing how to form the protective film 105 on the component main-bodies 110 on the workpiece holding body 20.

As shown by the chain-double-dashed line of FIG. 6, the protective film 105 is formed on the entire top surfaces 112 and the entire side peripheral surfaces 113 of the component main-bodies 110. The thickness of the protective film 105 is not particularly limited, and is 3 μm to 7 μm, for example. The material of the protective film 105 is not particularly limited. Typically, the protective film 105 is made of aluminum, titanium, chromium, copper, zinc, molybdenum, nickel, tungsten, tantalum, and oxide of them, nitride of them, or the like.

At this time, the second adhesive layer 222 of the adhesive sheet 22 comes in close contact with the bottom surface 111 of each component main-body 110, and thereby plays a role of shielding the plurality of bumps 103 from the environment around the component main-body 110. As a result, it is possible to, when forming a film, prevent a film-material from coming in contact with the bottom surface 111 of the component main-body 110 and prevent the film-material from adhering to the bumps 103, at the same time.

As the above-mentioned film-forming apparatus, typically, a sputtering apparatus or a vapor deposition apparatus is used. As the film-forming apparatus, a batch film-forming apparatus is preferably used, which is capable of accommodating the plurality of workpiece holding bodies 20 each holding the plurality of component main-bodies 110. Further, the film-forming apparatus is preferably configured to be capable of moving (rotating, swinging, etc.) each workpiece holding body 20 relative to film-forming sources such as sputtering cathodes in a film-forming chamber, in order to appropriately form the protective film 105 on the surfaces (the top surface 112 and the side peripheral surfaces 113) of each of all the component main-bodies 110 on each workpiece holding body 20. As such a film-forming apparatus, for example, a carousel sputtering apparatus is applicable.

The film-forming apparatus may include a processing unit that preprocesses the surface of a workpiece. Examples of preprocessing include ion beam irradiation processing, plasma processing, etching processing, and the like. The surface of a workpiece is preprocessed in order to, for example, remove grease and foreign substances and thereby increase its adhesiveness to a protective film.

FIG. 7 is a cross sectional view schematically showing a carousel sputtering apparatus according to an example.

As shown in FIG. 7, a sputtering apparatus 50 includes a vacuum chamber 1, which is a film-forming chamber. A rotary drum 2, which is a support body, is arranged substantially at the center of the vacuum chamber 1. A first film-forming zone 3, a second film-forming zone 4, and a preprocessing zone 5 are provided in order in the rotation direction of the rotary drum 2.

The peripheral surface 2a of the rotary drum 2 is a support surface that detachably supports the plurality of workpiece holding bodies 20, and includes necessary fixing mechanisms such as dampers. The rotary drum 2 includes a cooler capable of cooling down the peripheral surface 2a at a predetermined temperature or lower, inside the rotary drum 2. The cooler typically includes a circulation path, in which refrigerant such as cooling-water circulates.

The first film-forming zone 3 includes sputtering cathodes 6 having two electrodes, targets 7 arranged on the sputtering cathodes 6 at the side of the rotary drum 2, an AC power source 8 for applying an AC voltage to the sputtering cathodes 6, an Ar gas introducing system 9 for introducing Ar gas and other gas, and the like.

Similarly, the second film-forming zone 4 includes the sputtering cathodes 10 having two electrodes, the target 11 arranged on the sputtering cathodes 10 at the side of the rotary drum 2, the AC power source 12 for applying an AC voltage to the sputtering cathodes 10, the Ar gas introducing system 13 for introducing Ar gas and other gas, and the like.

The targets 7, 11 are made of a material the same as the material of the protective film 105. An openable-and-closable shutter 17 is provided between the targets 7 of the first film-forming zone 3 and the rotary drum 2. An openable-and-closable shutter 18 is provided between the target 11 of the second film-forming zone 4 and the rotary drum 2.

The preprocessing zone 5 is provided at an arbitrary location between the first film-forming zone 3 and the second film-forming zone 4. The preprocessing zone 5 includes an ion beam source 15 and a power source 16 for the ion beam source 15.

Note that the sputtering cathodes 6, 10, the targets 7, 11, and the AC power sources 8, 12 are film-forming sources for forming the protective film 105. Both the sputtering cathodes 6, 10 are AC sputtering sources. Alternatively, one of the sputtering cathodes 6, 10 may be a DC sputtering source, or both the sputtering cathodes 6, 10 may be DC sputtering sources. Further, magnetron magnetic circuits may further be provided in order to generate magnetic fields on the surfaces of the targets 7, 11.

In the step of forming the protective film 105 using the film-forming apparatus 50, each of the plurality of workpiece holding bodies 20 adhesively holds the plurality of component main-bodies 110. The plurality of workpiece holding bodies 20 are arrayed on the peripheral surface 2a of the rotary drum 2 in the rotation direction of the rotary drum 2. Then, while rotating the rotary drum 2 in the direction of the arrow of FIG. 7 at a constant speed, the ion beam irradiation processing in the preprocessing zone 5, the film-forming processing in the first film-forming zone 3, and the film-forming processing in the second film-forming zone 4 are executed in order. As a result, the protective film 105 is formed on the surfaces (the top surface 112, the side peripheral surfaces 113) of each component main-body 110 on each workpiece holding body 20.

In the present embodiment, the workpiece holding body 20 includes the heat-conductive sheet 212 arranged between the holder main-body 211 and the adhesive sheet 22. As a result, it is possible to cool down the component main-body 110 at a predetermined temperature or lower. Therefore it is possible to protect the component main-body 110 from heat of plasma when forming the protective film 105.

In this manner, the electronic component 100 is manufactured, in which the protective film 105 is formed on the surfaces of the component main-body 110. After completing the film-forming step, the workpiece holding bodies 20 are removed from the rotary drum 2 and are taken out from the film-forming apparatus 20. Then, the electronic components 100 are collected from the adhesive sheet 22 of each workpiece holding body 20.

The method of collecting the electronic components 100 are not particularly limited. Typically, each electronic component is peeled off from the adhesive sheet 22 by using a chuck such as a collet.

Note that the second adhesive layer 22 may be made of an adhesive resin material, whose adhesive force decreases when it is heated at a predetermined temperature or higher or is irradiated with UV light. Such an adhesive resin material has an advantage in which the electronic components 100 are collected easily.

[Replacement of Adhesive Sheet]

FIG. 8 (A to C) includes side-cross-sectional views each schematically showing the workpiece holding body 20 for illustrating the step of replacing the adhesive sheet 22.

After the electronic components 100 are removed, as shown in A of FIG. 8, the surface of the adhesive sheet 22 has pressure marks 107 and the like made by the protective film 105 and the plurality of bumps 103. Because of this, the adhesive sheet 22 cannot be used again, in many cases.

In view of the above, according to the present embodiment, as shown in B of FIG. 8, a used adhesive sheet 22 is peeled off from the holder 21 (the heat-conductive sheet 212). After that, as shown in C of FIG. 8, a new (unused) adhesive sheet 22 is attached to the holder 21 (the heat-conductive sheet 212). As a result, the second surface 22b (second adhesive layer) of the adhesive sheet 22 always has a satisfactory adhesive force (second adhesive force) and a satisfactory force to adhesively-hold a workpiece (the component main-body 110).

Further, according to the present embodiment, the adhesive sheet 22 protects the heat-conductive sheet 212 of the holder 21. So the holder 21 can be used again and again without replacing the heat-conductive sheet 212. In other words, since the relatively cheep adhesive sheet 22 is replaceable, the production cost may be reduced.

Further, according to the present embodiment, the first adhesive force of the first surface 22a (the first adhesive layer 221) of the adhesive sheet 22 bonded to the holder 21 is lower than the second adhesive force of the second surface (the second adhesive layer 222) of the adhesive sheet 22 that holds the component main-bodies 110. Therefore it is possible to easily peeling off the adhesive sheet 22 from the holder 21 having a relatively large area. Therefore it is possible to replace the adhesive sheet 22 without losing workability.

As described above, according to the present embodiment, the workpiece holding body 20 always has a satisfactory force to hold the component main-bodies 110 and, in addition, the adhesive sheet 22 can be replaced easily. As a result, the film is formed on the surfaces of each component main-body 110 appropriately and, in addition, each workpiece holding body 20 is recycled effectively. As a result, the productivity may be increased.

An embodiment of the present invention has been described above. As a matter of course, the present invention is not limited to the above-mentioned embodiment, but various modifications are applicable.

For example, in the above-mentioned embodiment, as an example of a workpiece, the component main-body 110 (the electronic component 100), i.e., a semiconductor package component, is described. Alternatively, the present invention is applicable to a plate-type workpiece such as a semiconductor wafer and a glass board.

Further, in the above-mentioned embodiment, the workpiece holding body, which is mainly used for film-forming processing, is described as an example. Alternatively, the present invention is applicable to a workpiece holding body, which is used for surface processing such as etching processing, plasma processing, processing of scattering charged particles (electron beam or ion beam), in addition, blast processing, and air-spray processing.

### REFERENCE SIGNS LIST

1 vacuum chamber (film-forming chamber)
2 rotary drum (support body)
7, 11 target
20 workpiece holding body
21 holder
211 holder main-body
212 heat-conductive sheet
22 adhesive sheet
22a first surface
22b second surface
220 base material
221 first adhesive layer
222 second adhesive layer
50 film-forming apparatus
100 electronic component
103 bump
105 protective film
110 component main-body

1. A workpiece holding body for surface processing, comprising:
a holder; and
an adhesive sheet including a first surface and a second surface, the first surface being bonded to the holder with a first adhesive force, the second surface being capable of holding a workpiece with a second adhesive force, the second adhesive force being higher than the first adhesive force.

2. The workpiece holding body according to claim 1, wherein
the adhesive sheet includes
a base material,
a first adhesive layer including the first surface, the first adhesive layer being layered on one surface of the base material, and
a second adhesive layer including the second surface, the second adhesive layer being layered on another surface of the base material.

3. The workpiece holding body according to claim 1, wherein
the second surface is capable of deforming depending on a form of an attached-surface of the workpiece.

4. The workpiece holding body according to claim 1, wherein
the holder includes
a holder main-body, and
a heat-conductive sheet arranged between the holder main-body and the adhesive sheet.

5. The workpiece holding body according to claim 1, wherein
the holder has a plate shape and is capable of holding a plurality of workpieces on one surface.

6. A film-forming apparatus, comprising:
a film-forming chamber;
a film-forming source provided in the film-forming chamber;
a support body provided in the film-forming chamber and having a support surface, the support surface being capable of supporting a workpiece; and
a workpiece holding body including
a holder detachably attached to the support surface, and
an adhesive sheet including a first surface and a second surface, the first surface being bonded to the holder with a first adhesive force, the second surface being configured to be capable of holding a workpiece with a second adhesive force, the second adhesive force being higher than the first adhesive force.

7. The film-forming apparatus according to claim 6, wherein
the support body includes a cooling mechanism capable of cooling down the support surface, and
the holder includes a holder main-body, and a heat-conductive sheet arranged between the holder main-body and the adhesive sheet.

8. The film-forming apparatus according to claim 7, wherein
the support body includes a rotary drum, the rotary drum being capable of rotating in the film-forming chamber and having the support surface formed on a peripheral surface.

9. The workpiece holding body according to claim 2, wherein
the second surface is capable of deforming depending on a form of an attached-surface of the workpiece.

10. The workpiece holding body according to claim 2, wherein
the holder includes
a holder main-body, and
a heat-conductive sheet arranged between the holder main-body and the adhesive sheet.

11. The workpiece holding body according to claim 3, wherein
the holder includes
a holder main-body, and
a heat-conductive sheet arranged between the holder main-body and the adhesive sheet.

12. The workpiece holding body according to claim 9, wherein
the holder includes
a holder main-body, and
a heat-conductive sheet arranged between the holder main-body and the adhesive sheet.

13. The workpiece holding body according to claim 2, wherein
the holder has a plate shape and is capable of holding a plurality of workpieces on one surface.

14. The workpiece holding body according to claim 3, wherein
the holder has a plate shape and is capable of holding a plurality of workpieces on one surface.

15. The workpiece holding body according to claim 4, wherein
the holder has a plate shape and is capable of holding a plurality of workpieces on one surface.

16. The workpiece holding body according to claim 9, wherein
the holder has a plate shape and is capable of holding a plurality of workpieces on one surface.

17. The workpiece holding body according to claim 10, wherein
the holder has a plate shape and is capable of holding a plurality of workpieces on one surface.

18. The workpiece holding body according to claim 11, wherein
the holder has a plate shape and is capable of holding a plurality of workpieces on one surface.

19. The workpiece holding body according to claim 12, wherein
the holder has a plate shape and is capable of holding a plurality of workpieces on one surface.
